(19) United States
(12) Patent Application Publication
(10) Pub. No.: US 2014/0104942 A1
(43) Pub. Date: Apr. 17, 2014

(54) RECESS GATE TRANSISTORS AND DEVICES INCLUDING THE SAME

(71) Applicant: Samsung Electronics Co., Ltd., Suwon-Si (KR)

(72) Inventors: Young-Gu JIN, Osan-si (KR); Ju Hwan JUNG, Seoul (KR); Yoon Dong PARK, Osan-si (KR)

(73) Assignee: SAMSUNG ELECTRONICS CO., LTD., Suwon-Si (KR)

(21) Appl. No.: 14/051,035

(22) Filed: Oct. 10, 2013

Related U.S. Application Data
(60) Provisional application No. 61/713,175, filed on Oct. 12, 2012.

(30) Foreign Application Priority Data
May 3, 2013 (KR) 10-2013-0049824

(51) Int. Cl. H01L 29/768; H01L 27/148; G11C 11/4074

(52) U.S. Cl. CPC H01L 29/768; G11C 11/4074; H01L 27/148
USPC 365/183; 257/244; 257/225

(57) ABSTRACT

A recess gate transistor includes: a drain region and a source region in a semiconductor substrate and doped with first-type impurities; a recess region recessed in the semiconductor substrate between the drain region and the source region; a gate insulation layer on the recess region, a gate electrode on the gate insulation layer filling the recess region; and a charge pocket region below the recess region and doped with second-type impurities. A semiconductor chip includes a plurality of recess gate transistors, and an image sensor includes a semiconductor chip including a plurality of recess gate transistors.

### CROSS-REFERENCE TO RELATED APPLICATIONS

This application claims priority under 35 U.S.C. §119(e) to U.S. provisional patent application No. 61/713,175 filed on Oct. 12, 2012, and under 35 U.S.C. §119(a) to Korean Patent Application No. 10-2013-0049824 filed on May 3, 2013, the entire contents of each of which are incorporated herein by reference.

### BACKGROUND

1. Field

Example embodiments of inventive concepts relate to single transistor memory structures, and more particularly, to recess gate transistors including recess gates, which may be used in semiconductor devices, and devices including the same.

2. Description of Conventional Art

Generally, a dynamic random access memory (DRAM) has a 1-transistor 1-capacitor cell structure. In order to reduce a load of manufacturing a capacitor for DRAM and facilitate the scaling of DRAM, a single transistor DRAM that does not include a capacitor has been developed. With the miniaturization of DRAM, a limit in reducing the distance between gates and a sensing margin decrease relatively rapidly in a planar structure of DRAM.

### SUMMARY

According to some example embodiments of inventive concepts, a recess gate transistor includes: a drain region and a source region in a semiconductor substrate and doped with first-type impurities; a recess region recessed into a region between the drain region and the source region; a gate insulation layer on the recess region; a gate electrode on the gate insulation layer to fill the recess region; and a charge pocket region which below the recess region and doped with second-type impurities.

A threshold voltage of the recess gate transistor or a current flowing in the recess gate transistor may be controlled according to an amount of charges integrated in the charge pocket region.

The recess gate transistor may further include: a first region formed below the charge pocket region and doped with the second-type impurities when the charge pocket region extends across the drain region and the source region. Here, a concentration of the second-type impurities in the charge pocket region may be higher than a concentration of the second-type impurities in the first region. Alternatively, the recess gate transistor may further include a first region formed below the drain region, the charge pocket region, and the source region and doped with the second-type impurities when the charge pocket region is formed below only the recess region. Here, a concentration of the second-type impurities in the charge pocket region may be higher than a concentration of the second-type impurities in the first region.

The recess gate transistor may further include: a channel region formed below the drain region, the recess region, and the source region, and doped with the first-type impurities; and a first region formed below the channel region, and doped with the second-type impurities. The charge pocket region formed below the recess region may have a recess structure in the first region and a concentration of the second-type impurities in the charge pocket region may be higher than a concentration of the second-type impurities in the first region.

According to other example embodiments of the inventive concept, a semiconductor chip includes a plurality of recess gate transistors. Each of the plurality of recess gate transistors includes: a drain region and a source region formed between device isolation films in a semiconductor substrate and having a first type; a recess region recessed into a region between the drain region and the source region; a gate insulation layer formed on the recess region; a gate electrode formed on the gate insulation layer to fill the recess region; and a charge pocket region formed below the recess region and having a second type.

The semiconductor chip may further include a voltage generator configured to: apply a ground voltage to the source region through a source line; apply a first voltage to the drain region through a bit line; and apply a second voltage to the gate electrode through a word line during a read operation when the first-type is an n-type and the second-type is a p-type. The first voltage may be higher than the ground voltage, and the second voltage may be higher than the first voltage.

The semiconductor chip may further include a voltage generator configured to: apply a ground voltage to the source region through a source line; apply a first voltage to the drain region through a bit line; and apply a second voltage to the gate electrode through a word line during a write operation when the first type is an n-type and the second type is a p-type. The first voltage may be higher than the ground voltage, and the second voltage may be lower than the first voltage.

The semiconductor chip may further include a voltage generator configured to: apply a ground voltage to the source region through a source line; apply a first voltage to the drain region through a bit line, and apply the first voltage to the gate electrode through a word line during a write operation when the first type is an n-type and the second type is a p-type. The first voltage may be higher than the ground voltage.

The semiconductor chip may further include a voltage generator configured to: apply a ground voltage to the source region through a source line; apply the ground voltage to the drain region through a bit line; and apply a word line voltage to the gate electrode through a word line during a hold operation when the first type is an n-type and the second type is a p-type. The word line voltage may be lower than the ground voltage.

The semiconductor chip may further include a voltage generator configured to: apply a ground voltage to the source region through a source line; apply a first voltage to the drain region through a bit line; and apply a second voltage to the gate electrode through a word line during a read operation when the first type is a p-type and the second type is an n-type. The first voltage may be lower than the ground voltage, and the second voltage may be lower than the first voltage.

The semiconductor chip may further include a voltage generator configured to: apply a ground voltage to the source region through a source line; apply a first voltage to the drain region through a bit line; and apply a second voltage to the gate electrode through a word line during a write operation when the first type is a p-type and the second type is an n-type. The first voltage may be lower than the ground voltage, and the second voltage may be higher than the first voltage.

The semiconductor chip may further include a voltage generator configured to: apply a ground voltage to the source region through a source line; apply a first voltage to the drain region through a bit line; and apply the first voltage to the gate electrode through a word line during a write operation when the first type is a p-type and the second type is an n-type. The first voltage may be lower than the ground voltage.

The semiconductor chip may further include a voltage generator configured to: apply a ground voltage to the source region through a source line; apply the ground voltage to the drain region through a bit line; and apply a word line voltage to the gate electrode through a word line during a hold operation when the first type is a p-type and the second type is an n-type. The word line voltage may be higher than the ground voltage.

According to at least some other example embodiments of inventive concepts, an image sensor includes a plurality of recess gate transistors. Each of the recess gate transistors includes: a lower region formed below the charge pocket region and is doped with the first type of impurities. The charge pocket region and the lower region may form a photoelectric conversion region.

At least one other example embodiment provides a recess gate transistor including: a source region and a drain region in a substrate, the source region and the drain region being doped with a first impurity type; a gate structure in a recessed region of the substrate between the source region and the drain region; and a charge pocket region below the gate structure, the charge pocket region being doped with a second impurity type.

According to at least some example embodiments, the recess gate transistor may further include: a first region doped with the second impurity type below the charge pocket region, the first region having a doping concentration that is less than a doping concentration of the charge pocket region.

According to at least some other example embodiments, the recess gate transistor may further include: a first region doped with the first impurity type below the charge pocket region.

A width of the charge pocket region may be substantially equal to a width of the recessed region.

The recess gate transistor may further include: a channel region between the recessed region and the charge pocket region, the channel region being doped with the first impurity type.

### BRIEF DESCRIPTION OF THE DRAWINGS

The above and other features and advantages of inventive concepts will become more apparent by describing in detail example embodiments thereof with reference to the attached drawings in which:

FIG. 1 is a diagram of a single transistor memory structure according to example embodiments of inventive concepts;

FIGS. 2 through 4 are diagrams of a single transistor memory structure depending on a substrate and a doping concentration according to different example embodiments of inventive concepts;

FIG. 5 is a diagram of an array having a plurality of single transistor memory structures according to example embodiments of inventive concepts;

FIG. 6 is a diagram of an array having a plurality of single transistor memory structures according to other example embodiments of inventive concepts;

FIGS. 7 through 10 are diagrams for explaining the operation of an n-channel metal oxide semiconductor (NMOS) single transistor memory structure according to example embodiments of inventive concepts;

FIG. 11 is a diagram of voltages defined by the operations of a single transistor memory structure;

FIG. 12 is a waveform diagram of voltages defined by the operations of the single transistor memory structure illustrated in FIG. 1;

FIG. 13 is a diagram of a single transistor memory structure according to other example embodiments of inventive concepts;

FIGS. 14 through 16 are diagrams of a single transistor memory structure depending on a substrate and a doping concentration according to different example embodiments of inventive concepts;

FIGS. 17 through 20 are diagrams for explaining the operation of a p-channel metal oxide semiconductor (PMOS) single transistor memory structure according to some example embodiments of inventive concepts;

FIG. 21 is a waveform diagram of voltages defined by the operations of the single transistor memory structure illustrated in FIG. 13;

FIG. 22 is a block diagram of an image processing system including a single transistor memory structure according to some example embodiments of inventive concepts; and

FIG. 23 is a block diagram of an image processing system including a single transistor memory structure according to other example embodiments of inventive concepts.

### DETAILED DESCRIPTION

Inventive concepts now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Hereinafter, a first-type impurity is one of a p-type impurity and an n-type impurity and a second-type impurity is the other one of the p-type impurity and the n-type impurity.

It is assumed that a concentration “n+” or “p+” of impurities is higher than a concentration “n” or “p” of impurities and a concentration “n” or “p” of impurities is higher than a concentration of “n−” or “p−” of impurities.

In addition, in cross-sectional views of a single transistor memory structure (that may be simplified as a “single transistor memory”), the position (or location) of each of regions is conceptually illustrated and processes of manufacturing each region may vary within the scope of the inventive concept. The single transistor memory is a recess gate transistor with a recess structure.

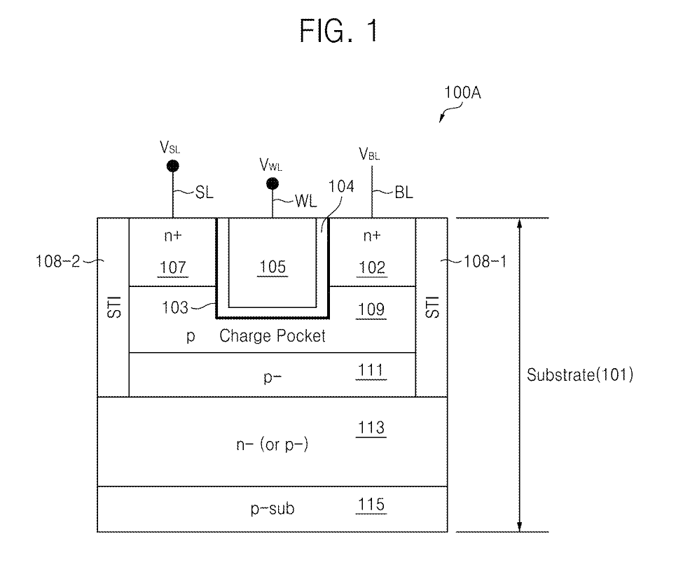

FIG. 1 is a diagram of a single transistor memory structure 100A according to example embodiments of inventive concepts.

In the NMOS single transistor memory 100A, a third region 115 may be doped with p-type impurities.

A second region 113 is formed on or above the third region 115. The second region 113 may be doped with n- or p-type impurities. Two device isolation films 108-1 and 108-2 are formed on or above the second region 113. The device isolation films 108-1 and 108-2 may be formed using shallow trench isolation (STI).

An active region and a non-active region may be isolated or defined by the device isolation films 108-1 and 108-2. A first region 111 is formed between the device isolation films 108-1 and 108-2. A charge pocket region 109 is formed on or above the first region 111.

A threshold voltage of the NMOS single transistor memory 100A or the amount of current flowing in a channel of the NMOS single transistor memory 100A may be determined depending on the amount of charge generated (or integrated) in the charge pocket region 109. A drain region 102 and a source region 107 are formed on or above the charge pocket region 109.

A recess region 103 is recessed into a region between the drain region 102 and the source region 107. The recess region 103 may have such a width and depth that maximize the distance between the drain region 102 and the source region 107. Accordingly, the width and the depth of the recess region 103 may vary with manufacturers' design.

A gate insulation layer (or gate oxide layer) 104 is formed on the recess region 103. A gate electrode 105 is formed on the gate insulation layer 104 to fill the recess region 103. In other words, a space on the gate insulation layer 104 may be filled with the gate electrode 105. The gate electrode 105 may be formed of poly silicon or metal.

The first region 111 may be doped with p-type impurities using an ion-implantation process and the charge pocket region 109 may be doped with p-type impurities using the ion-implantation process. The concentration “p” of p-type impurities in the charge pocket region 109 is higher than the concentration “p−” of p-type impurities in the first region 111.

The drain and source regions 102 and 107 are doped with n-type impurities using the ion-implantation process.

A bit line voltage VBL may be applied to the drain region 102 through a bit line BL, a word line voltage VWL may be applied to the gate electrode 105 through a word line WL, and a source line voltage VSL may be applied to the source region 107 through a source line SL. An electrical contact means, e.g., a contact, a via, or a metal, may be formed between the bit line BL and the drain region 102, between the word line WL and the gate electrode 105, and/or between the source line SL and the source region 107.

The first region 111 including p-type impurities and the second region 113 including n-type impurities may form a photoelectric conversion region. The second region 113 including n-type impurities and the third region 115 including p-type impurities may also form a photoelectric conversion region. The photoelectric conversion region may perform the function of a photodiode.

Accordingly, when light is incident on the third region 115, the NMOS single transistor memory 100A may be implemented as a pixel of an image sensor using backside illumination (BIS).

The elements 102, 103, 107, 109, 111, 113, and 115 may be formed in a semiconductor substrate, e.g., a silicon substrate 101.

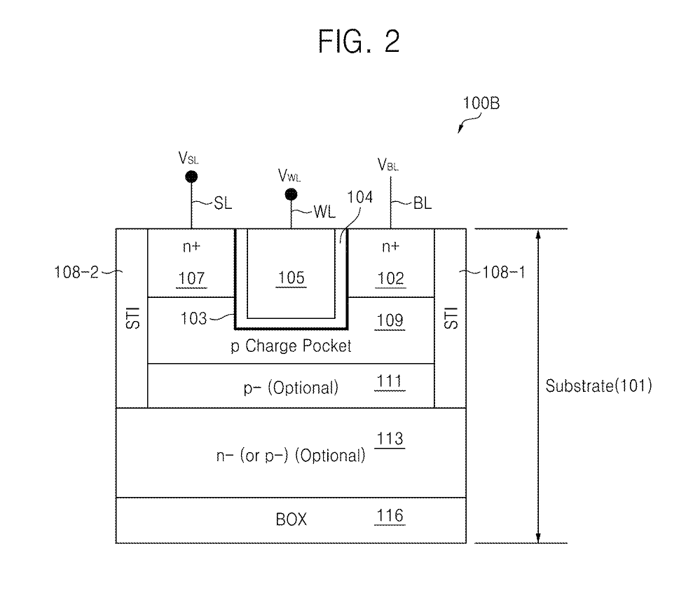

FIGS. 2 through 4 are diagrams of a single transistor memory depending on a substrate and a doping concentration according to different example embodiments of inventive concepts.

FIG. 2 shows a silicon-on-insulator (SOI)-NMOS single transistor memory 100B. The structure and the operations of the NMOS single transistor memory 100B illustrated in FIG. 2 are substantially the same as those of the NMOS single transistor memory 100A illustrated in FIG. 1, except for a buried oxide (BOX) region 116. According to example embodiments, the first region 111 and the second region 113 may not be formed in the NMOS single transistor memory 100B.

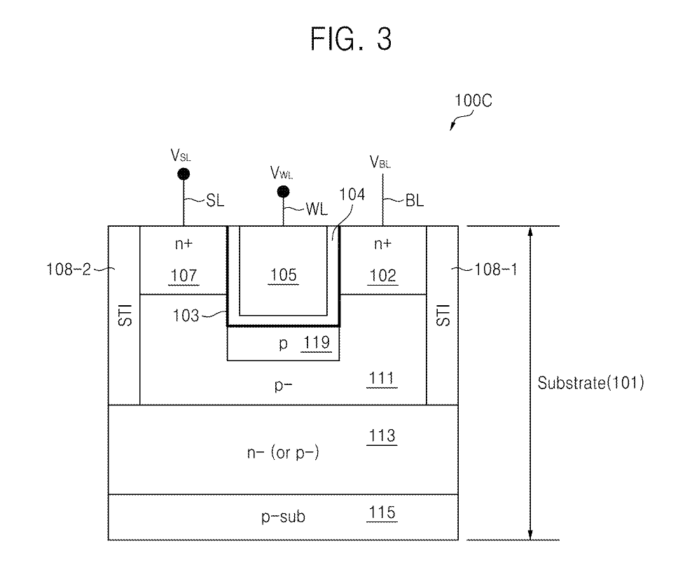

FIG. 3 shows an NMOS single transistor memory 100C including a local charge pocket region 119. Except for the position of the charge pocket region 119, the structure and the operations of the NMOS single transistor memory 100C illustrated in FIG. 3 are substantially the same as those of the NMOS single transistor memory 100A illustrated in FIG. 1.

While the charge pocket region 109 illustrated in FIG. 1 is positioned below the drain region 102, the recess region 103, and the source region 107; the charge pocket region 119 illustrated in FIG. 3 is positioned below only the recess region 103.

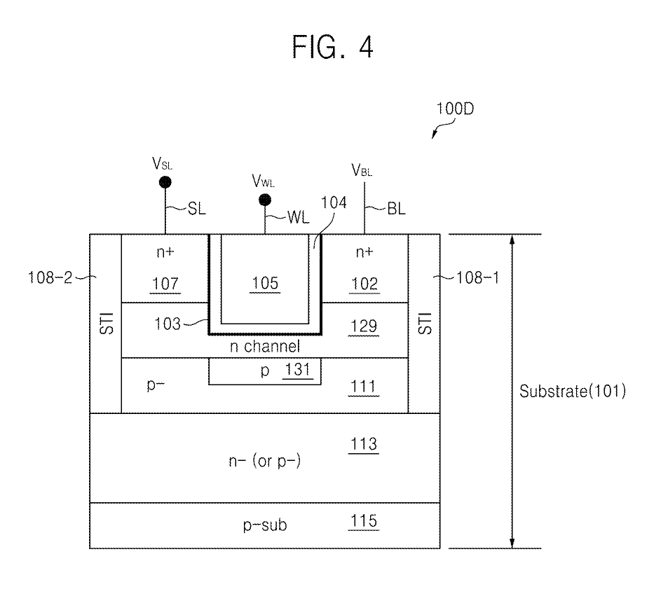

FIG. 4 shows an NMOS single transistor memory 100D with a threshold voltage adjusted. Except for the position of a channel region 129 and a charge pocket region 131, the structure and the operations of the NMOS single transistor memory 100D illustrated in FIG. 4 are substantially the same as those of the NMOS single transistor memory 100A illustrated in FIG. 1.

The channel region 129 is formed on or above the first region 111. The drain region 102, the recess region 103, and the source region 107 are formed on or above the channel region 129. The charge pocket region 131 is formed in the first region 111.

The charge pocket region 131 may be doped with p-type impurities using an ion-implantation process and the channel region 129 may be doped with the n-type impurities using the ion-implantation process. For example, the concentration “n+” of n-type impurities in the drain region 102 and the source region 107 may be higher than the concentration “n” of n-type impurities in the channel region 129. Since the channel region 129 is implemented separately, the threshold voltage of the NMOS single transistor memory 100D has been adjusted structurally.

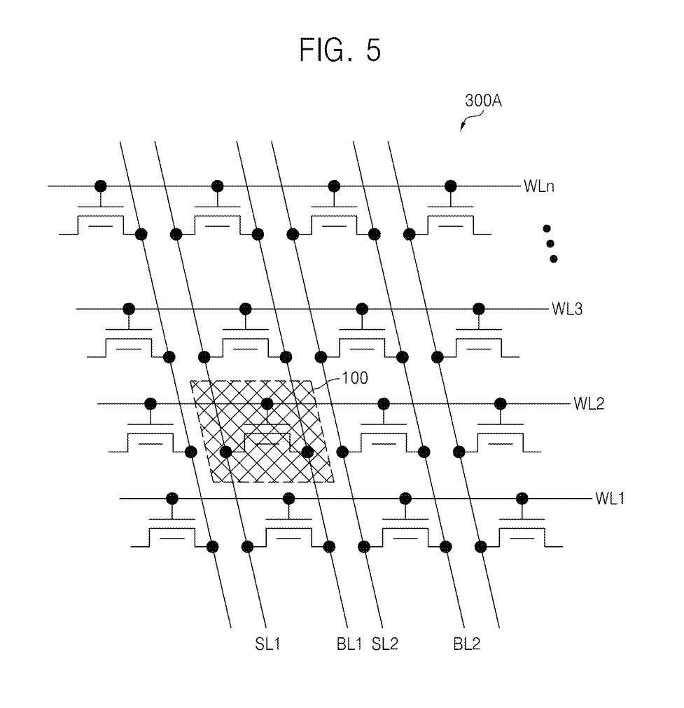

FIG. 5 is a diagram of an array 300A having a plurality of single transistor memories according to example embodiments of inventive concepts. Referring to FIGS. 1 through 5, the array 300A includes a plurality of word lines WL1 through WLn, a plurality of bit lines BL1 and BL2, a plurality of source lines SL1 and SL2, and a plurality of NMOS single transistor memories 100A through 100D (collectively denoted by 100). Source lines for respective NMOS single transistor memories 100 in a row are separated from each other.

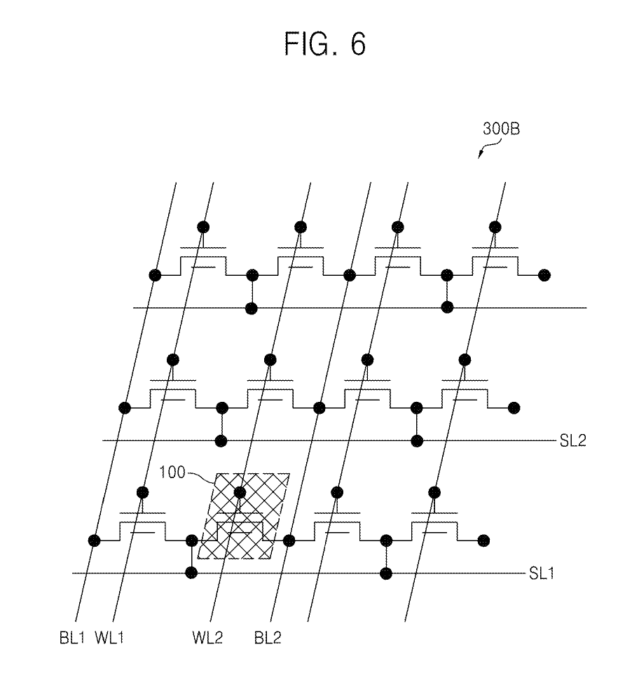

FIG. 6 is a diagram of an array 300B having a plurality of single transistor memory structures according to other example embodiments of inventive concepts. The array 300B includes a plurality of word lines WL1 and WL2, a plurality of bit lines BL1 and BL2, a plurality of source lines SL1 and SL2, and a plurality of NMOS single transistor memories 100.

Referring to FIG. 6, NMOS single transistor memories 100 arranged in a first row share the first source line SL1 with each other and NMOS single transistor memories 100 arranged in a second row share the second source line SL2 with each other. In other words, NMOS single transistor memories 100 arranged in each row share a source line with each other.

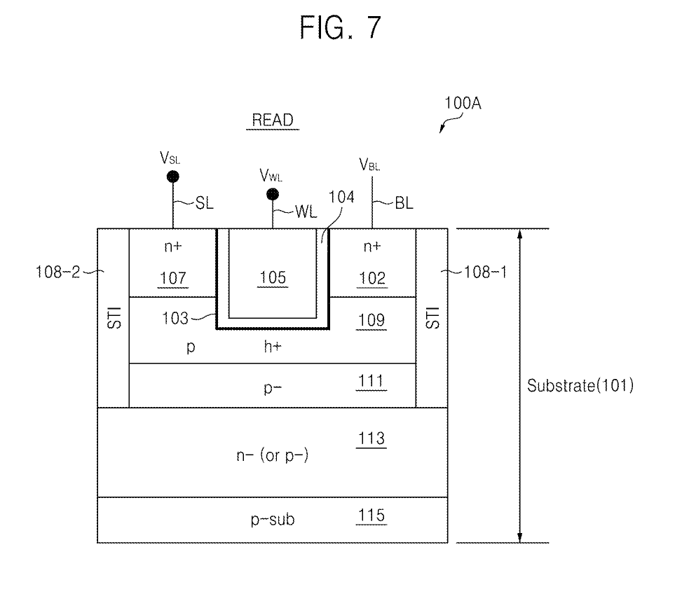

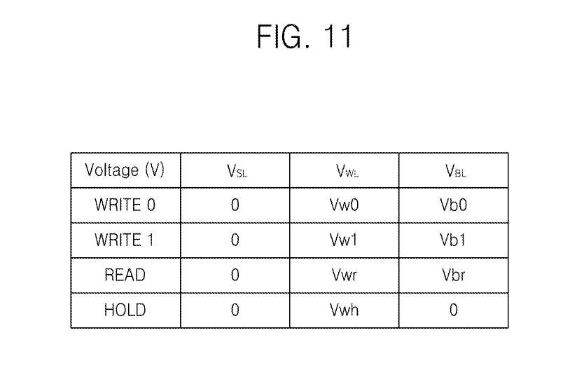

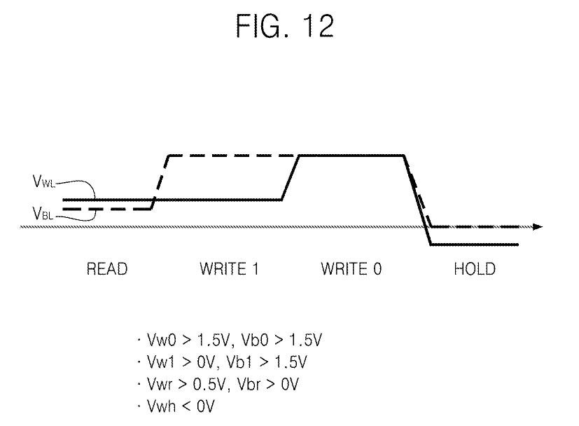

FIGS. 7 through 10 are diagrams for explaining the operation of the NMOS single transistor memory 100A according to some example embodiments of inventive concepts. FIG. 11 is a diagram of voltages defined by the operations of the single transistor memory 100A. FIG. 12 is a waveform diagram of voltages defined by the operations of the single transistor memory 100A.

For convenience' sake in the description, 0, 0.5, and 1.5 V are shown as examples in FIG. 12. These voltages may vary with embodiments.

A read operation READ, a first write operation WRITE0, a second write operation WRITE1, and a hold operation HOLD of the NMOS single transistor memory 100A will be described in detail with reference to FIGS. 7 through 12.

Read Operation READ

The read operation READ of the NMOS single transistor memory 100A will be described in detail with reference to FIGS. 7, 11, and 12.

Referring to FIG. 7, a threshold voltage of the NMOS single transistor memory 100A or the amount of current flowing in a channel of the NMOS single transistor memory 100A is determined or controlled by charges, e.g., the amount of holes, in the charge pocket region 109 of the NMOS single transistor memory 100A.

During the read operation READ, the bit line voltage V_{BL} (=Vbr) is applied to the drain region 102 through the bit line BL, the word line voltage V_{WL} (=Vwr) is applied to the gate electrode 105 through the word line WL, and a ground voltage is applied to the source region 107 through the source line SL.

In other words, during the read operation READ, the word line voltage V_{WL} (=Vwr) is higher than the bit line voltage V_{BL} (=Vbr).

First Write Operation WRITE0

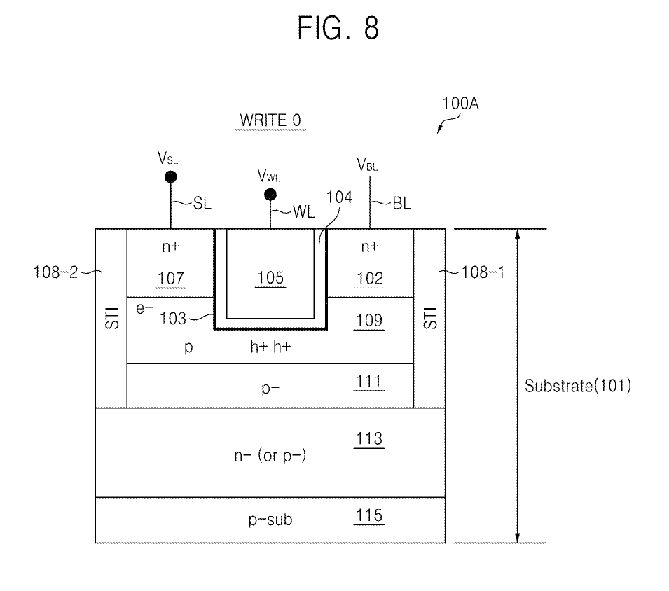

The first write operation WRITE0 of the NMOS single transistor memory 100A will be described in detail with reference to FIGS. 8, 11, and 12. The first write operation WRITE0 is an operation of writing data “0” to the NMOS single transistor memory 100A.

During the first write operation WRITE0, the bit line voltage V_{BL} (=Vb0) is applied to the drain region 102 through the bit line BL, the word line voltage V_{WL} (=Vw0) is applied to the gate electrode 105 through the word line WL, and the ground voltage is applied to the source region 107 through the source line SL. Accordingly, current flows from the drain region 102 to the source region 102 through the charge pocket region 109.

For instance, holes are supplied to the charge pocket region 109 through impact ionization or band-to-band tunneling (BTBT), so that the current flows. Here, the impact ionization is a process in which one energetic charge carrier loses energy due to the generation of other charge carrier in a material like semiconductor.

As illustrated in FIG. 12, the bit line voltage V_{BL} (=Vb0) may be the same as the word line voltage V_{WL} (=Vw0). In other embodiments, the bit line voltage V_{BL} (=Vb0) may be different from the word line voltage V_{WL} (=Vw0).

Second Write Operation WRITE1

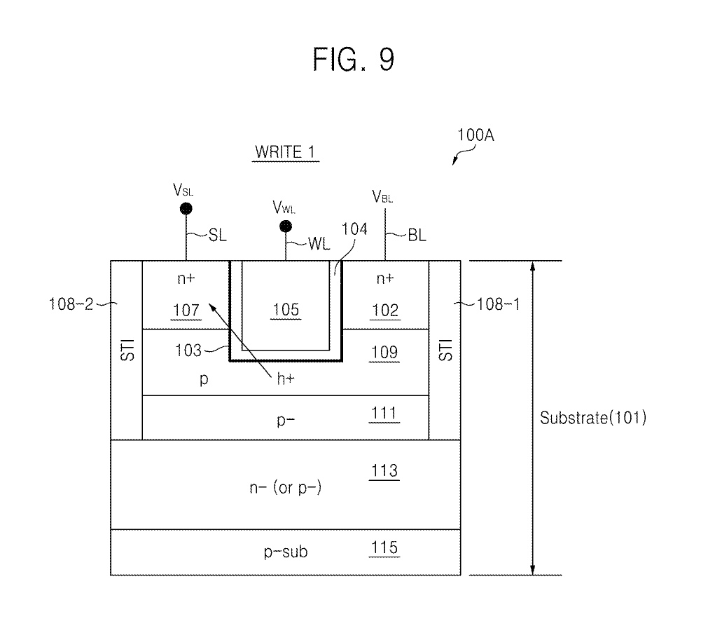

The second write operation WRITE1 of the NMOS single transistor memory 100A will be described in detail with reference to FIGS. 9, 11, and 12. The second write operation WRITE1 is an operation of writing data “1” to the NMOS single transistor memory 100A.

During the second write operation WRITE1, the bit line voltage V_{BL} (=Vb1) is applied to the drain region 102 through the bit line BL, the word line voltage V_{WL} (=Vw1) is applied to the gate electrode 105 through the word line WL, and the ground voltage is applied to the source region 107 through the source line SL. Accordingly, holes in the charge pocket region 109 flows to the source region 107. During the second write operation WRITE1, the bit line voltage V_{BL} (=Vb1) is higher than the word line voltage V_{WL} (=Vw1).

Hold Operation HOLD

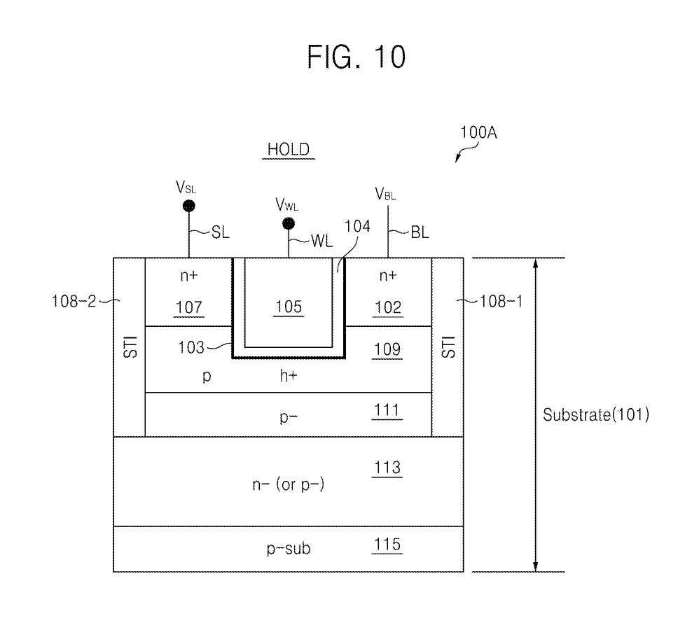

The hold operation HOLD of the NMOS single transistor memory 100A will be described in detail with reference to FIGS. 10 through 12.

During the hold operation HOLD, the ground voltage is applied to the drain region 102 through the bit line BL, the word line voltage V_{WL} (=Vwh) is applied to the gate electrode 105 through the word line WL, and the ground voltage is applied to the source region 107 through the source line SL. In other words, during the hold operation HOLD, 0 V or a negative voltage is applied to the word line WL and holes are held in the charge pocket region 109.

The read operation READ, the first write operation WRITE0, the second write operation WRITE1, and the hold operation HOLD of the NMOS single transistor memories 100B through 100D can be understood from FIGS. 11 and 12. Thus, detailed descriptions thereof will be omitted.

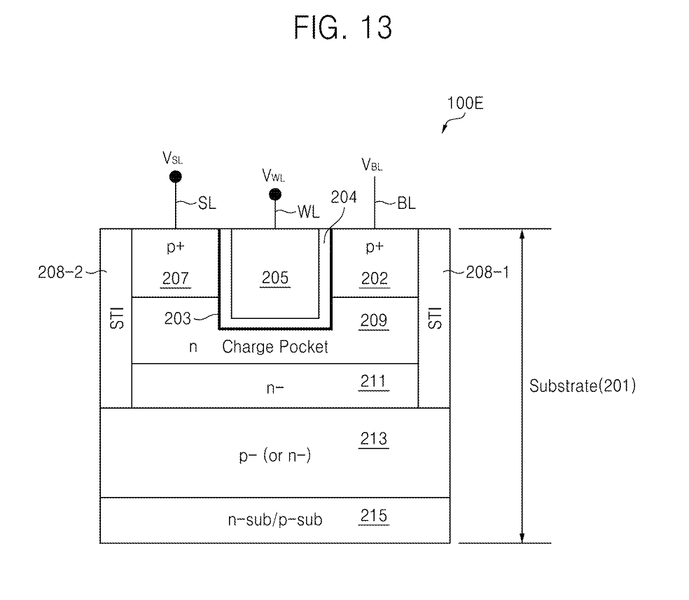

FIG. 13 is a diagram of a single transistor memory structure according to other example embodiments of inventive concepts.

In the PMOS single transistor memory 100E, a third region 215 may be doped with n-type impurities.

A second region 213 is formed on or above the third region 215. The second region 213 may be doped with p- or n-type impurities. Two device isolation films 208-1 and 208-2 are formed on of above the second region 213. The device isolation films 208-1 and 208-2 may be formed using STI.

A first region 211 is formed between the device isolation films 208-1 and 208-2. A charge pocket region 209 is formed on or above the first region 211. A threshold voltage of the PMOS single transistor memory 100E or the amount of current flowing in a channel of the PMOS single transistor memory 100E may be determined depending on the amount of charge generated (or integrated) in the charge pocket region 209. A drain region 202 and a source region 207 are formed on or above the charge pocket region 209.

A recess region 203 is recessed into a region between the drain region 202 and the source region 207. The recess region 203 may have such a width and depth that maximize the distance between the drain region 202 and the source region 207. Accordingly, the width and the depth of the recess region 203 may vary with manufacturers' design. A gate insulation layer 204 is formed on the recess region 203.

A gate electrode 205 is formed on the gate insulation layer 204 to fill the recess region 203. The gate electrode 205 may be formed of poly silicon or metal. The first region 211 may be doped with n-type impurities using an ion-implantation process and the charge pocket region 209 may be doped with n-type impurities using the ion-implantation process. The concentration “n” of n-type impurities in the charge pocket region 209 may be higher than the concentration “n−” of n-type impurities in the first region 211.

The drain and source regions 202 and 207 are doped with p-type impurities using the ion-implantation process.

A bit line voltage V_{BL} may be applied to the drain region 202 through a bit line BL, a word line voltage V_{WL} may be applied to the gate electrode 205 through a word line WL, and a source line voltage V_{SL} may be applied to the source region 207 through a source line SL. An electrical contact means may be formed between the bit line BL and the drain region 202, between the word line WL and the gate electrode 205, and/or between the source line SL and the source region 207.

The first region 211 including n-type impurities and the second region 213 including p-type impurities may form a photoelectric conversion region. The second region 213 including p-type impurities and the third region 215 including n-type impurities may also form a photoelectric conversion region. The photoelectric conversion region may perform the function of a photodiode.

Accordingly, when light is incident on the third region 215, the PMOS single transistor memory 100E may be implemented as a pixel of an image sensor using BIS. The elements 202, 203, 207, 209, 211, 213, and 215 may be formed in a semiconductor substrate, e.g., a silicon substrate 201.

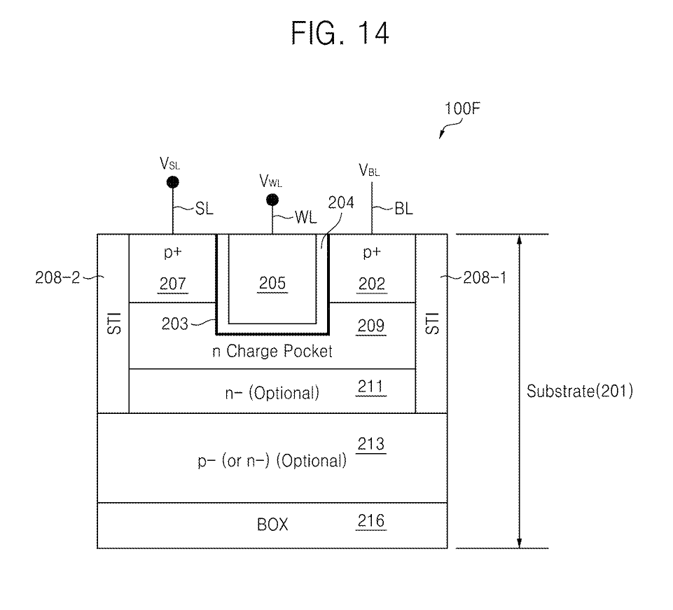

FIGS. 14 through 16 are diagrams of a single transistor memory depending on a substrate and a doping concentration according to different example embodiments of inventive concepts.

FIG. 14 shows a SOI-PMOS single transistor memory 100F. The structure and the operations of the PMOS single transistor memory 100F illustrated in FIG. 14 are substantially the same as those of the PMOS single transistor memory 100E illustrated in FIG. 13, except for a BOX region 216. The first region 211 and the second region 213 may not be formed in the PMOS single transistor memory 100E.

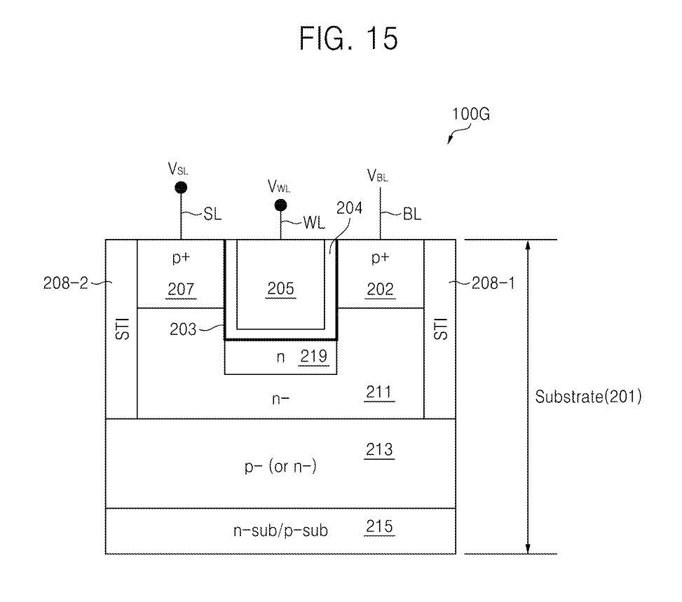

FIG. 15 shows a PMOS single transistor memory 100G including a local charge pocket region 219. Except for the position of the charge pocket region 219, the structure and the operations of the PMOS single transistor memory 100G illustrated in FIG. 15 are substantially the same as those of the PMOS single transistor memory 100E illustrated in FIG. 13.

While the charge pocket region 209 illustrated in FIG. 13 is positioned below the drain region 202, the recess region 203, and the source region 207; the charge pocket region 219 illustrated in FIG. 15 is positioned below only the recess region 203.

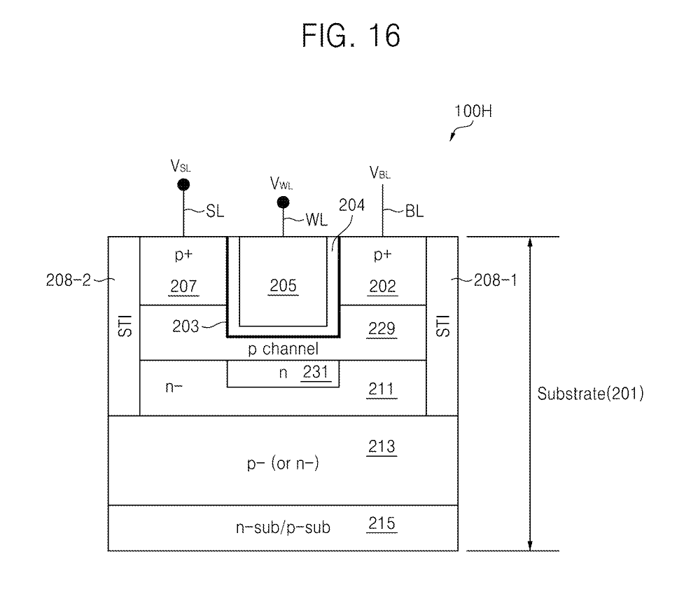

FIG. 16 shows a PMOS single transistor memory 100H with a threshold voltage adjusted. Except for the position of a channel region 229 and a charge pocket region 231, the structure and the operations of the PMOS single transistor memory 100H illustrated in FIG. 16 are substantially the same as those of the PMOS single transistor memory 100E illustrated in FIG. 13.

The channel region 229 is formed on or above the first region 211. The drain region 202, the recess region 203, and the source region 207 are formed on or above the channel region 229.

The charge pocket region 231 is formed in the first region 211. The charge pocket region 231 may be doped with n-type impurities using an ion-implantation process and the channel region 229 may be doped with the p-type impurities using the ion-implantation process. The concentration “p+” of p-type impurities in the drain region 202 and the source region 207 may be higher than the concentration “p” of p-type impurities in the channel region 229. The threshold voltage of the PMOS single transistor memory 100H has been adjusted structurally.

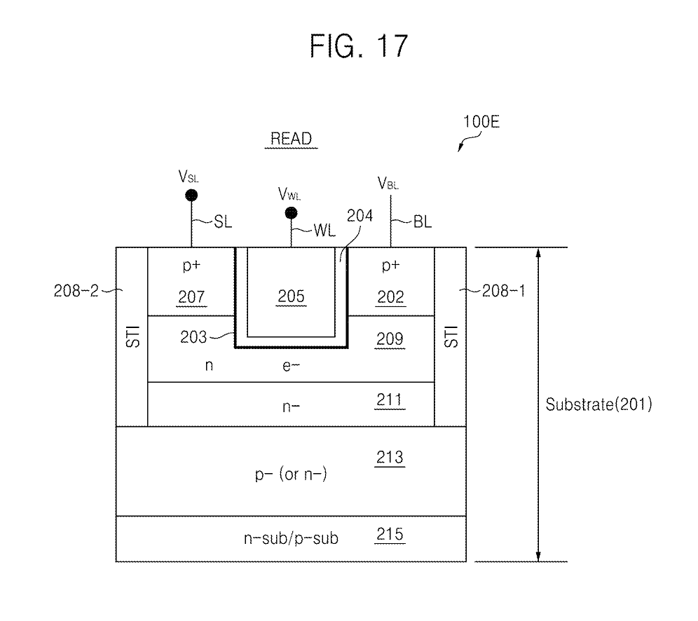

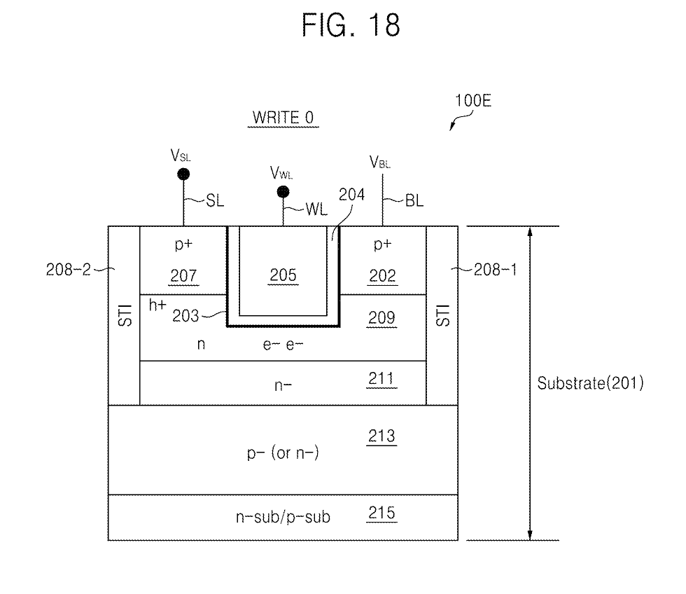

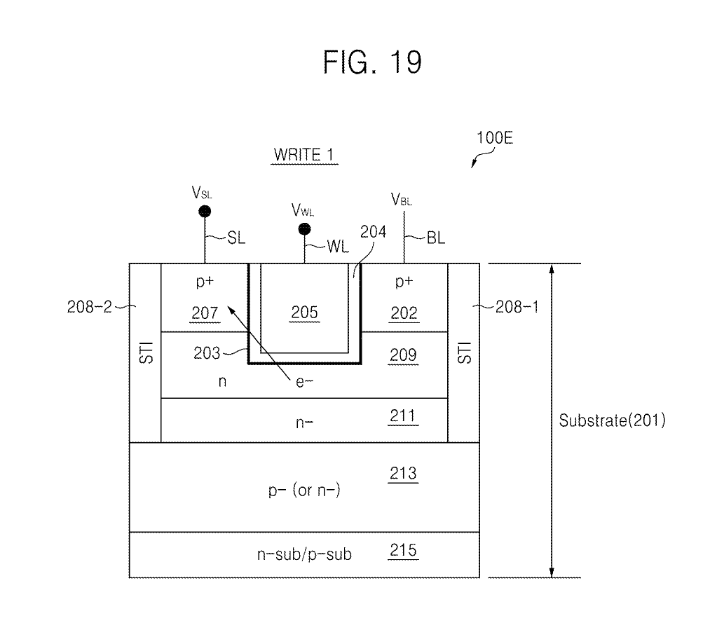

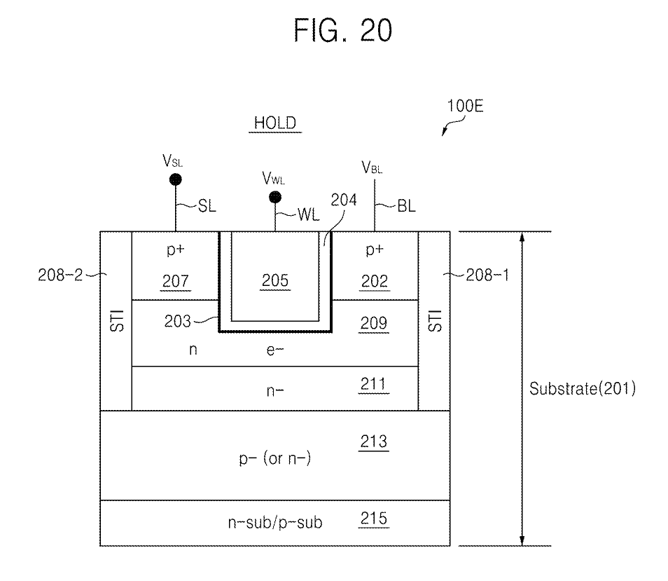

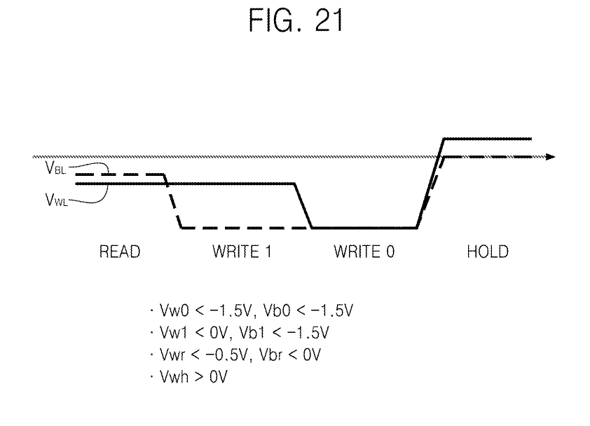

FIGS. 17 through 20 are diagrams for explaining the operation of the PMOS single transistor memory 100E according to some example embodiments of inventive concepts. FIG. 21 is a waveform diagram of voltages defined by the operations of the single transistor memory 100E.

For convenience' sake in the description, 0, −0.5, and −1.5 V are shown as examples in FIG. 21. These voltages may vary with embodiments.

A read operation READ, a first write operation WRITE0, a second write operation WRITE1, and a hold operation HOLD of the PMOS single transistor memory 100E will be described in detail with reference to FIGS. 11 and 17 through 21.

Read Operation READ

The read operation READ of the PMOS single transistor memory 100E will be described in detail with reference to FIGS. 11, 17, and 21.

Referring to FIG. 17, a threshold voltage of the PMOS single transistor memory 100E or the amount of current flowing in a channel of the PMOS single transistor memory 100E is determined or controlled by charges, e.g., the amount of electrons, in the charge pocket region 209 of the PMOS single transistor memory 100E.

During the read operation READ, the bit line voltage V_{BL} (=Vbr) is applied to the drain region 202 through the bit line BL, the word line voltage V_{WL} (=Vwr) is applied to the gate electrode 205 through the word line WL, and a ground voltage is applied to the source region 207 through the source line SL. The bit line voltage V_{BL} (=Vbr) may be lower than the ground voltage and the word line voltage V_{WL} (=Vwr) may be lower than −0.5 V. In other words, during the read operation READ, the word line voltage V_{WL} (=Vwr) is lower than the bit line voltage V_{BL} (=Vbr).

First Write Operation WRITE0

The first write operation WRITE0 of the PMOS single transistor memory 100E will be described in detail with reference to FIGS. 11, 18, and 21.

During the first write operation WRITE0, the bit line voltage V_{BL} (=Vb0) is applied to the drain region 202 through the bit line BL, the word line voltage V_{WL} (=Vw0) is applied to the gate electrode 205 through the word line WL, and the ground voltage is applied to the source region 207 through the source line SL. The bit line voltage V_{BL} (=Vb0) may be lower than −1.5 V and the word line voltage V_{WL} (=Vw0) may also be lower than −1.5 V.

Accordingly, current flows from the source region 207 to the drain region 202 through the charge pocket region 209. For instance, electrons are supplied to the charge pocket region 209 through impact ionization or BTBT, so that the current flows.

As illustrated in FIG. 21, the bit line voltage V_{BL} (=Vb0) may be the same as the word line voltage V_{WL} (=Vw0). In other embodiments, the bit line voltage V_{BL} (=Vb0) may be different from the word line voltage V_{WL} (=Vw0).

Second Write Operation WRITE1

The second write operation WRITE1 of the PMOS single transistor memory 100E will be described in detail with reference to FIGS. 11, 19, and 21.

During the second write operation WRITE1, the bit line voltage V_{BL} (=Vb1) is applied to the drain region 202 through the bit line BL, the word line voltage V_{WL} (=Vw1) is applied to the gate electrode 205 through the word line WL, and the ground voltage is applied to the source region 207 through the source line SL.

The bit line voltage V_{BL} (=Vb1) may be lower than −1.5 V and the word line voltage V_{WL} (=Vw1) may also be lower than 0 V. Accordingly, electrons in the charge pocket region 209 flows to the source region 207. During the second write operation WRITE1, the bit line voltage V_{BL} (=Vb1) is lower than the word line voltage V_{WL} (=Vw1).

Hold Operation HOLD

The hold operation HOLD of the PMOS single transistor memory 100E will be described in detail with reference to FIGS. 11, 20, and 21.

During the hold operation HOLD, the ground voltage is applied to the drain region 202 through the bit line BL, the word line voltage V_{WL} (=Vwh) is applied to the gate electrode 205 through the word line WL, and the ground voltage is applied to the source region 207 through the source line SL. In other words, during the hold operation HOLD, 0 V or a positive voltage is applied to the word line WL and electrons are held in the charge pocket region 209.

The read operation READ, the first write operation WRITE0, the second write operation WRITE1, and the hold operation HOLD of the PMOS single transistor memories 100F through 100H can be understood from FIGS. 11 and 21. Thus, detailed descriptions thereof will be omitted.

When the PMOS single transistor memories 100E through 100H are implemented in an image sensor, the third region 215 illustrated in FIGS. 13 through 16 may be implemented as an area including n-type impurities.

However, when the PMOS single transistor memories 100E through 100H are not implemented in an image sensor, the third region 215 illustrated in FIGS. 13 through 16 may be implemented as a region including p-type impurities.

As described above with reference to FIGS. 1 through 21, the type and the concentration of impurities doped in at least one of the first region 111 or 211, the second region 113 or 213, and the third region 115 or 215 may be variously changed; and at least one of these regions may not be implemented or formed according to the characteristics of products. The position of the charge pocket regions 109, 119, 131, 209, 219, and 231 and the position of the channel regions 129 and 229 may also be variously changed.

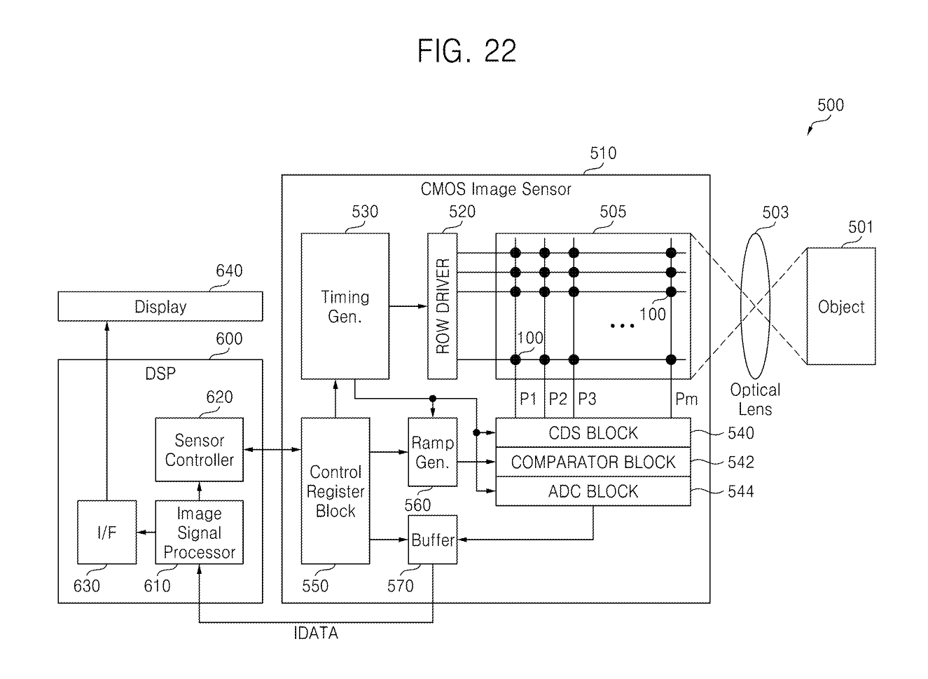

FIG. 22 is a block diagram of an image processing system 500 including a single transistor memory structure according to some example embodiments of inventive concepts. Referring to FIGS. 1 through 22, the image processing system 500 may be implemented as a portable electronic device such as a digital camera, a camcorder, a mobile telephone, a smart phone, a mobile Internet device (MID), or a tablet personal computer (PC).

The image processing system 500 includes an optical lens 503, complementary metal oxide semiconductor (CMOS) image sensor 510, a digital signal processor (DSP) 600, and a display 640. The image processing system 500 may not include the optical lens 503 in other embodiments.

The CMOS image sensor 510 generates image data IDATA corresponding to an object 501 captured through the optical lens 503. The CMOS image sensor 510 includes a pixel array 505, a row driver 520, a timing generator 530, a correlated double sampling (CDS) block 540, a comparator block 542, an analog-to-digital converter (ADC) block 544, a control register block 550, a ramp generator 560, and a buffer 570.

The pixel array 505 includes a plurality of pixels. Each of the pixels may be implemented by any one of the single transistor memories 100A through 100H (collectively denoted by 100) described with reference to FIGS. 1 through 21.

The pixel array 505 includes pixels 100 arranged in a matrix form. The row driver 520 drives the control signals V_{BL}, V_{WL}, and V_{SL} for controlling the operation of the pixels 100 to the pixel array 505 according to the control of the timing generator 530. The row driver 520 may function as a voltage generator that generates the control signals V_{BL}, V_{WL}, and V_{SL}.

The timing generator 530 controls the operations of the row driver 520, the CDS block 540, the ADC block 542, and the ramp generator 560 according to the control of the control register block 550.

The CDS block 540 performs CDS on pixel signals P1 through Pm (where “m” is a natural number) output from respective column lines implemented in the pixel array 505. At this time, the pixel signals P1 through Pm are signals output from the pixels, i.e., the single transistor memories 100 functioning as pixels.

The comparator block 542 compares CDS pixel signals output from the CDS block 540 with a ramp signal output from the ramp generator 560 and outputs a plurality of comparison signals.

The ADC block 544 converts the comparison signals output from the comparator block 542 into digital signals and outputs the digital signals to the buffer 570. The control register block 550 controls the operations of the timing generator 530, the ramp generator 560, and the buffer 570 according to the control of the DSP 600. The buffer 570 transmits the image data IDATA corresponding to the digital signals output from the ADC block 544 to the DSP 600.

The DSP 600 includes an image signal processor 610, a sensor controller 620, and an interface (I/F) 630. The image signal processor 610 controls the interface 630 and the sensor controller 620 which controls the control register block 550.

The CMOS image sensor 510 and the DSP 600 may be implemented together in a single package, e.g., a multi-chip package. Alternatively, the CMOS image sensor 510 and the image signal processor 610 may be implemented together in a single package, e.g., a multi-chip package.

The image signal processor 610 processes the image data IDATA transmitted from the buffer 570 and transmits processed image data to the I/F 630.

The sensor controller 620 generates various control signals for controlling the control register block 550 according to the control of the image signal processor 610. The I/F 630 transmits the image data processed by the image signal processor 610 to the display 640. The display 640 displays the image data output from the I/F 630.

The display 640 may be implemented by a thin film transistor liquid crystal display (TFT-LCD), a light emitting diode (LED) display, an organic LED (OLED) display, an active-matrix OLED (AMOLED) display, or a flexible display.

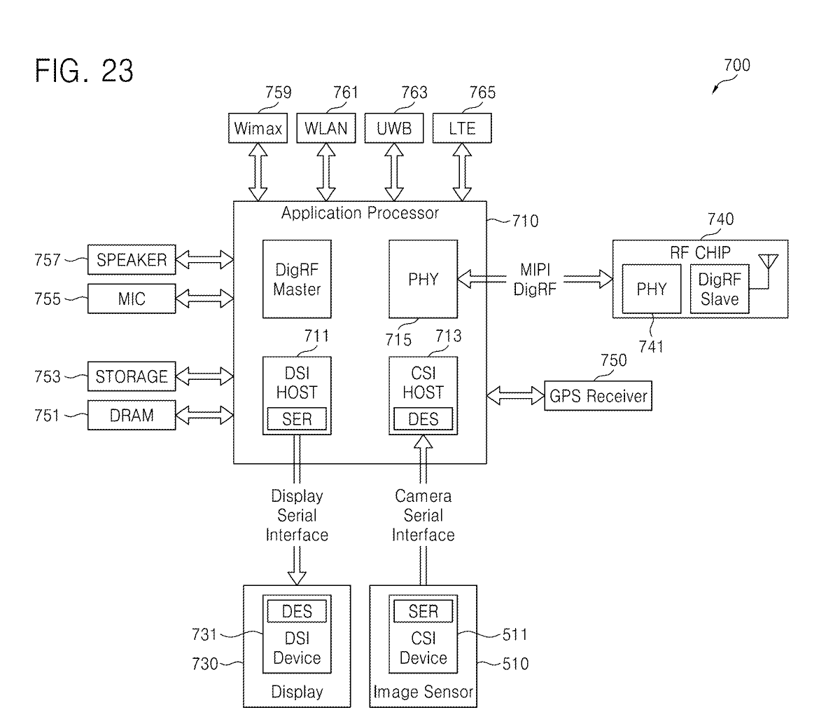

FIG. 23 is a block diagram of an image processing system 700 including a single transistor memory structure according to other example embodiments of inventive concepts. Referring to FIGS. 1 through 23, the image processing system 700 may be implemented as a portable electronic device which can use or support mobile industry processor interface (MIPI). The image processing system 700 may be implemented in an integrated circuit (IC) or a system on chip (SoC).

The portable electronic device may be a personal digital assistant (PDA), a portable media player (PMP), a mobile phone, a smart phone, a tablet PC, a mobile Internet device (MID), or a digital camera.

The image processing system 700 includes an application processor (AP) 710, the CMOS image sensor 510, and a display 730.

A camera serial interface (CSI) host 713 implemented in the AP 710 may perform serial communication with a CSI device 511 included in the CMOS image sensor 510 through CSI. At this time, a deserializer DES and a serializer SER may be implemented in the CSI host 713 and the CSI device 511, respectively.

A display serial interface (DSI) host 711 implemented in the AP 710 may perform serial communication with a DSI device 731 included in the display 730 through DSI. A serializer SER and a deserializer DES may be implemented in the DSI host 711 and the DSI device 7311, respectively. The deserializer DES and the serializer SER may process electrical signals or optical signals.

The image processing system 700 may also include a radio frequency (RF) chip 740 communicating with the AP 710. A physical layer (PHY) 715 of the AP 710 and a PHY 741 of the RF chip 740 may communicate data with each other according to MIPI DigRF.

The image processing system 700 may further include a global positioning system (GPS) receiver 750, a memory 751 like dynamic random access memory, a data storage 753 implemented by a non-volatile memory like NAND flash memory, a microphone (MIC) 755, and a speaker 757. The image processing system 700 may communicate with external devices using a worldwide interoperability for microwave access (Wimax) 759, a wireless local area network (WLAN) 761, an ultra-wideband (UWB) 763, or a long term evolution (LTE™) network 765.

The image processing system 700 may also communicate with external devices using Bluetooth or WiFi. The single transistor memories 100 described above may be implemented in a semiconductor chip.

As described above, according to some example embodiments of inventive concepts, a recess gate transistor is reduced and/or minimized while a distance between a source region and a drain region is increased and/or maximized.

The recess gate transistor allows a channel to be more adequately influenced by charges integrated in a charge pocket region formed below a recess gate.

In addition, the recess gate transistor functions as a pixel for a CMOS image sensor using BSI. The recess gate transistor is also used as an embedded memory of an IC or a SoC.

While inventive concepts have been particularly shown and described with reference to exemplary embodiments thereof, it will be understood by those of ordinary skill in the art that various changes in forms and details may be made therein without departing from the spirit and scope of inventive concepts as defined by the following claims.

What is claimed is:

1. A recess gate transistor comprising:
a drain region and a source region in a substrate, the drain region and the source region being doped with first-type impurities;
a recess region in the substrate between the drain region and the source region;
a gate insulation layer in the recess region;
a gate electrode on the gate insulation layer in the recess region; and
a charge pocket region below the recess region and doped with second-type impurities.

2. The recess gate transistor of claim 1, wherein a threshold voltage of the recess gate transistor or a current flowing in the recess gate transistor is controlled according to an amount of charges integrated in the charge pocket region.

3. The recess gate transistor of claim 1, wherein the charge pocket region extends across the drain region and the source region, and the recess gate transistor further includes,
a first region below the charge pocket region and doped with the second-type impurities, and wherein
a concentration of the second-type impurities in the charge pocket region is higher than a concentration of the second-type impurities in the first region.

4. The recess gate transistor of claim 1, wherein the charge pocket region is below only the recess region, and the recess gate transistor further includes,
a first region below the drain region, the charge pocket region, and the source region, the first region being doped with the second-type impurities, and wherein
a concentration of the second-type impurities in the charge pocket region is higher than a concentration of the second-type impurities in the first region.

5. The recess gate transistor of claim 1, further comprising:
a channel region below the drain region, the recess region, and the source region, the channel region being doped with the first-type impurities; and
a first region below the channel region and doped with the second-type impurities; wherein
the charge pocket region below the recess region has a recess structure in the first region, and
a concentration of the second-type impurities in the charge pocket region is higher than a concentration of the second-type impurities in the first region.

6. A semiconductor chip comprising:
a plurality of recess gate transistors, each of the plurality of recess gate transistors including,
a drain region and a source region between device isolation films in a substrate, the drain region and the source region doped with a first-type impurities,
a recess region recessed in the substrate between the drain region and the source region,
a gate insulation layer in the recess region,
a gate electrode on the gate insulation layer filling the recess region, and
a charge pocket region below the recess region and doped with second-type impurities.

7. The semiconductor chip of claim 6, further comprising:
a voltage generator configured to, during a read operation when the first-type is an n-type and the second-type is a p-type,
apply a ground voltage to the source region through a source line,
apply a first voltage to the drain region through a bit line, and
apply a second voltage to the gate electrode through a word line, wherein the first voltage is higher than the ground voltage, and the second
voltage is higher than the first voltage.

8. The semiconductor chip of claim 6, further comprising:
a voltage generator configured to, during a write operation when the first-type is an n-type and the second-type is a p-type,
apply a ground voltage to the source region through a source line,
apply a first voltage to the drain region through a bit line, and
apply a second voltage to the gate electrode through a word line, wherein the first voltage is higher than the ground voltage and the second
voltage is lower than the first voltage.

9. The semiconductor chip of claim 6, further comprising:
a voltage generator configured to, during a write operation when the first-type is an n-type and the second-type is a p-type,
apply a ground voltage to the source region through a source line,
apply a first voltage to the drain region through a bit line, and
apply the first voltage to the gate electrode through a word line, wherein the first voltage is higher than the ground voltage.

10. The semiconductor chip of claim 6, further comprising:
a voltage generator configured to, during a hold operation when the first-type is an n-type and the second-type is a p-type,
apply a ground voltage to the source region through a source line,
apply the ground voltage to the drain region through a bit line, and
apply a word line voltage to the gate electrode through a word line, the word line voltage being lower than the ground voltage.

11. The semiconductor chip of claim 6, further comprising:
a voltage generator configured to, during a read operation when the first-type is a p-type and the second-type is an n-type,
apply a ground voltage to the source region through a source line,
apply a first voltage to the drain region through a bit line, and
apply a second voltage to the gate electrode through a word line, wherein the first voltage is lower than the ground voltage and the second
voltage is lower than the first voltage.

12. The semiconductor chip of claim 6, further comprising:
a voltage generator configured to, during a write operation when the first-type is a p-type and the second-type is an n-type,
apply a ground voltage to the source region through a source line,
apply a first voltage to the drain region through a bit line, and
apply a second voltage to the gate electrode through a word line, wherein the first voltage is lower than the ground voltage and the second
voltage is higher than the first voltage.

13. The semiconductor chip of claim 6, further comprising:
a voltage generator configured to, during a write operation when the first-type is a p-type and the second-type is an n-type,
apply a ground voltage to the source region through a source line,
apply a first voltage to the drain region through a bit line, and
apply the first voltage to the gate electrode through a word line, wherein the first voltage is lower than the ground voltage.

14. The semiconductor chip of claim 6, further comprising:
a voltage generator configured to, during a hold operation when the first-type is a p-type and the second-type is an n-type,
apply a ground voltage to the source region through a source line,
apply the ground voltage to the drain region through a bit line, and
apply a word line voltage to the gate electrode through a word line, wherein the word line voltage is higher than the ground voltage.

15. An image sensor comprising:
the semiconductor chip of claim 6, each of the recess gate transistors further including,
a lower region below the charge pocket region and doped with the first-type of impurities, the charge pocket region and the lower region forming a photoelectric conversion region.

16. A recess gate transistor comprising:
a source region and a drain region in a substrate, the source region and the drain region being doped with a first impurity type;
a gate structure in a recessed region of the substrate between the source region and the drain region; and
a charge pocket region below the gate structure, the charge pocket region being doped with a second impurity type.

17. The recess gate transistor of claim 16, further comprising:
a first region doped with the second impurity type below the charge pocket region, the first region having a doping concentration that is less than a doping concentration of the charge pocket region.

18. The recess gate transistor of claim 16, further comprising:
a first region doped with the first impurity type below the charge pocket region.

19. The recess gate transistor of claim 16, wherein a width of the charge pocket region is substantially equal to a width of the recessed region.

20. The recess gate transistor of claim 16, further comprising:
a channel region between the recessed region and the charge pocket region, the channel region being doped with the first impurity type.
